(19) United States
(12) Patent Application Publication
(10) Pub. No.: US 2017/0218517 A1
(43) Pub. Date: Aug. 3, 2017

(54) METHOD OF FORMING NITRIDE FILM

(71) Applicant: TOKYO ELECTRON LIMITED, Tokyo (JP)

(72) Inventors: Noriaki FUKIAGE, Nirasaki City (JP); Takayuki KARAKAWA, Nirasaki City (JP); Akihiro KURIBAYASHI, Nirasaki City (JP); Takeshi OYAMA, Nirasaki City (JP); Jun OGAWA, Nirasaki City (JP)

(21) Appl. No.: 15/420,322

(22) Filed: Jan. 31, 2017

(30) Foreign Application Priority Data
Feb. 1, 2016 (JP) 2016-017022
Dec. 2, 2016 (JP) 2016-234902

(51) Int. Cl. C23C 16/511; C23C 16/34; C23C 16/455

(52) U.S. Cl. CPC C23C 16/511; C23C 16/45525; C23C 16/345

(57) ABSTRACT

A method of forming a nitride film in a fine recess formed in a surface of a substrate to be processed, by repeating a process, which includes adsorbing a film forming raw material gas onto the substrate and nitriding the adsorbed film forming raw material gas. The nitriding the adsorbed film forming raw material gas includes converting a NH₃ gas as a nitriding gas, and an adsorption inhibiting gas for inhibiting adsorption of the NH3 gas into radicals and supplying the radicals onto the substrate.

### CROSS-REFERENCE TO RELATED APPLICATIONS

This application claims the benefits of Japanese Patent Application Nos. 2016-017022 and 2016-234902, filed on Feb. 1, 2016 and Dec. 2, 2016, respectively, in the Japan Patent Office, the disclosures of which are incorporated herein in their entirety by reference.

### TECHNICAL FIELD

The present disclosure relates to a method of forming a nitride film such as a silicon nitride film.

### BACKGROUND

In a sequence of manufacturing a semiconductor device, there exists a process of forming a nitride film such as a silicon nitride film (SiN film) or the like, serving as an insulating film, on a semiconductor wafer represented by a silicon wafer. A chemical vapor deposition (CVD) method is employed for such a SiN film forming process.

When a SiN film (CVD-SiN film) is buried in a trench by means of the CVD method, the film tends to be thicker at the frontage of the trench than at the bottom thereof and, as miniaturization of devices advances, voids or seams in the film becomes problematic.

In contrast, an atomic layer deposition method (ALD method) is known as a technology capable of forming a film conformably in a fine trench with a better step coverage than the CVD method. The ALD method is also used to bury a SiN film in the trench.

However, as the device miniaturization further advances, even if conformal film formation using the ALD method is performed, it becomes difficult to bury the SiN film in a trench while preventing voids or seams.

### SUMMARY

Some embodiments of the present disclosure provide to a method of forming a nitride film, which is capable of burying a nitride film in a fine recess while preventing voids or seams.

According to one of the embodiments, there is provided a method of forming a nitride film in a fine recess formed in a surface of a substrate to be processed, by repeating a process including adsorbing a film forming raw material gas onto the substrate; and nitriding the adsorbed film forming raw material gas, wherein the nitriding the adsorbed film forming raw material gas includes converting a NH₃ gas as a nitriding gas, and an adsorption inhibiting gas for inhibiting adsorption of the NH3 gas into radicals and supplying the radicals onto the substrate.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A and 1B are views used to explain adsorption states of NH₃* in a case where only NH3* is supplied during nitridation and in a case where both of NH₃* and H₂* are supplied during nitridation.

FIG. 2 is a schematic graphical view showing a change in probability of existence of H₂* in a recess in a depth direction.

FIG. 3 is a sectional view schematically showing a film formation state of a SiN film in a case where NH₃* and H₂* are supplied during nitridation.

FIG. 4 is a sectional view showing a structure of a semiconductor wafer used in a specific example of a method of forming a nitride film, according to one embodiment of the present disclosure.

FIG. 5 is a sectional view showing a state of a film forming process in carrying out the method of forming a nitride film, according to one embodiment of the present disclosure.

FIG. 6 is a sectional view showing a state of a film forming process in carrying out the method of forming a nitride film, according to one embodiment of the present disclosure, wherein FIG. 6 shows a state in which the film formation is further advanced from the state of FIG. 5.

FIG. 7 is a sectional view showing a state of a film forming process in carrying out the method of forming a nitride film, according to one embodiment of the present disclosure, wherein it shows a state in which burying of the film in a recess has been completed.

FIG. 8 is a cross-sectional view showing one example of a film forming apparatus used to carry out a film forming method of the present disclosure.

FIG. 9 is a longitudinal sectional view of the film forming apparatus of FIG. 8, which is taken along line A-A′ in FIG. 8.

FIG. 10 is a plan view showing the film forming apparatus of FIG. 9.

FIG. 11 is an enlarged longitudinal sectional view showing a first region of the film forming apparatus of FIG. 9.

FIG. 12 is a bottom view showing a precursor gas introduction unit installed in the first region.

FIG. 13 is an enlarged longitudinal sectional view showing one nitriding region in a second region of the film forming apparatus of FIG. 9.

FIG. 14 is a flowchart for explaining a processing operation of the film forming apparatus of FIG. 9.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

In the present disclosure, a nitride film is formed by an ALD method. In one embodiment, a case where a silicon nitride film (SiN film) is formed as the nitride film will be described by way of an example.

### Outline of Method of Forming Silicon Nitride Film

A substrate to be processed in which a recess such as a trench or a hole is formed in a surface of the substrate is prepared, and adsorption and nitridation of a Si precursor (film forming raw material gas) are repeated for the substrate a predetermined number of times to form a silicon nitride film.

In the nitridation, a NH₃ gas as a nitriding gas and an H₂ gas as an adsorption inhibiting gas are activated by plasma or the like and the nitridation is performed with generated NH₃ radicals (NH³*) and H₂ radicals (H₂*). Note that NH₃* and H₂* contain all radicals generated by the NH₃ gas and radicals generated by the H₂ gas, respectively.

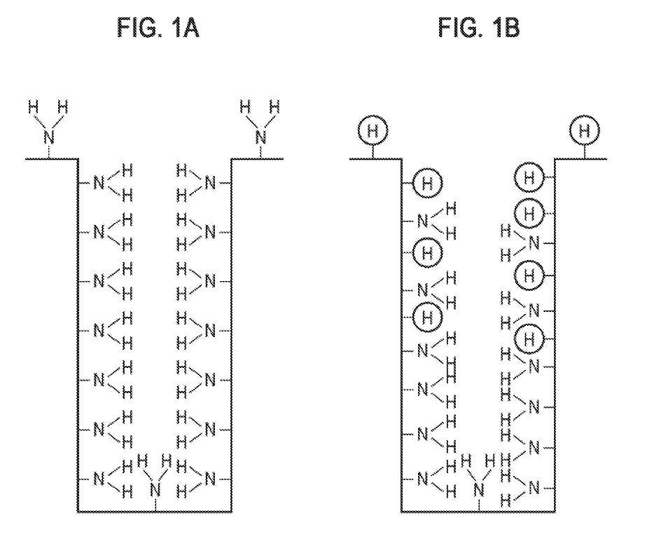

Since NH₃* is easily adsorbed to Si and its lifetime is relatively long, when only NH₃* is supplied, it is adsorbed, as an amino group (—NH₂), on the entire inner wall of the recess and makes a nitriding reaction with the film forming raw material gas, as shown in FIG. 1A. Consequently, conformal film formation (which may be referred to as deposition) is performed.

In contrast, when H₂* is used in addition to NH₃* in the nitridation, H₂* inhibits adsorption of NH₃* to Si. Therefore, an adsorption site of NH₃* decreases. Further, the adsorption inhibiting effect of H₂* is larger at the upper portion of the recess and is smaller at the bottom of the recess.

Therefore, in the case of using H₂* in addition to NH₃*, the adsorption site of NH₃* becomes relatively small at the upper portion of the recess and becomes relatively large at the bottom of the recess, as shown in FIG. 1B.

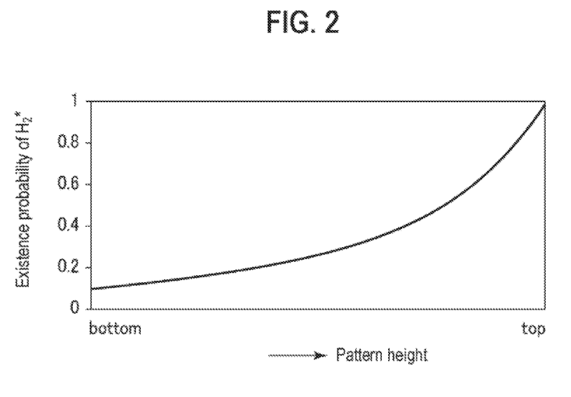

In this manner, because of its short lifetime, H2* can be used to control the adsorption of NH₃* at the upper portion and bottom portion of the recess. FIG. 2 is a schematic graphical view showing a change in probability of existence of H₂* in a recess of 200 nm at 40 nmφ in a depth direction. As shown in FIG. 2, the existence probability of H₂* decreases toward the bottom of the recess, which indicates that the lifetime of H₂* is short.

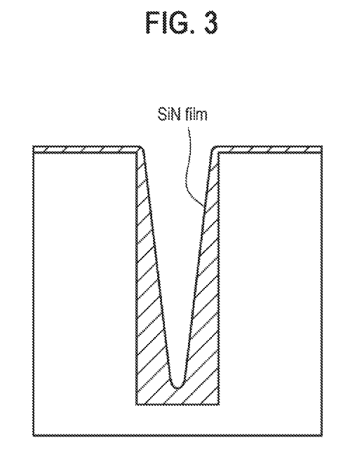

in this way, as the adsorption site of NH₃* becomes relatively small at the upper portion of the recess and becomes relatively large at the bottom of the recess, the nitriding reaction of the Si precursor, which is the film forming raw material gas, proceeds more easily at the bottom of the recess than the upper portion of the recess and the deposition rate of a SiN film becomes accordingly larger at the bottom of the recess than the upper portion of the recess. For this reason, as shown in FIG. 3, a V-shaped film is formed to be thicker at the bottom of the recess and thinner at the upper portion of the recess. Therefore, even in a case of burying a film in a fine recess, it is possible to extremely effectively prevent a situation such as forming the film with voids left inside the recess.

However, in order to effectively obtain such an effect, it is desirable to form a film by means of an apparatus in which H₂* is generated immediately above a substrate to be processed so that H₂* having a short lifetime is not deactivated at the upper portion of the substrate, and is supplied onto the substrate.

### Specific Example of Method of Forming Nitride Film

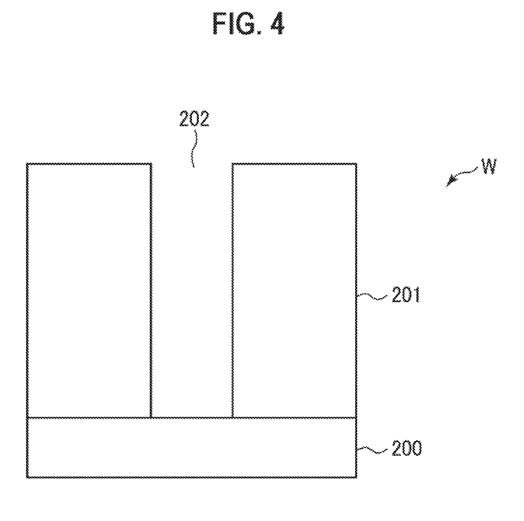

Hereinafter, a specific example of a method of forming a nitride film according to one embodiment of the present disclosure will be described with reference to FIG. 4.

First, as shown in FIG. 4, a semiconductor wafer as a substrate to be processed (hereinafter simply referred to as a wafer) W in which an insulating film (SiO₂ film) 201 is formed on a Si base body 200 and a fine recess 202 is formed in the insulating film 201 is prepared. At this time, the fine recess 202 is a trench or a hole and its size is about 20 to 100 nm in width or diameter, 50 to 1000 nm in height and about 5 to 50 in aspect ratio. For example, the width is 30 nm, the height is 300 nm and the aspect ratio is 10.

Next, formation of a SiN film on such a wafer W is started. At this time, for example, the wafer W repeatedly passes through a Si precursor adsorption region for adsorbing a Si precursor as a raw material gas and a plurality of nitridation regions in which a process for nitriding the Si precursor is performed, and the Si precursor adsorption and nitridation are repeated a predetermined number of times. Gas separation by a separation gas is performed between the Si precursor adsorption region and the nitridation regions.

In the step of adsorbing the Si precursor, the Si precursor is conformably formed on the inner wall of the recess 202 with a molecular layer level of extremely thin film. As the Si precursor, monosilane (SiH₄), disilane (Si₂H₆), monochlorosilane (MCS; SiH₃Cl), dichlorosilane (DCS; SiH₂Cl₂), trichlorosilane (TCS; SiHCl₃), silicon tetrachloride (STC; SiCl₄), hexachlorodisilane (HCD; Si₂Cl₆) or the like can be used. Of these, DCS can be suitably used.

In the nitridation, as described above, a NH₃ gas as a nitriding gas and a H₂ gas as an adsorption inhibiting gas are activated by plasma or the like to be NH₃* and H₂*, respectively, which are supplied onto the wafer W and are adsorbed into the recess 202. At this time, as described above, since the lifetime of H₂* is short, the adsorption inhibiting effect is larger at the upper portion of the recess 202 and smaller at the bottom of the recess 202. Therefore, an adsorption site of NH₃* becomes relatively small at the upper portion of the recess 202 and becomes relatively large at the bottom of the recess 202.

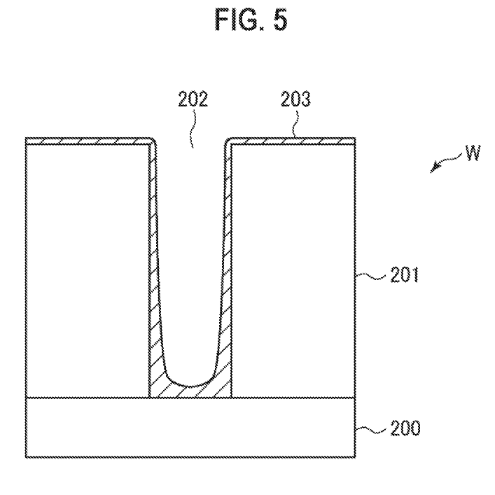

Therefore, by repeating the adsorption and nitridation of the Si precursor, a nitriding reaction of the Si precursor proceeds further at the bottom of the recess 202 and, during the formation of the SiN film, as shown in FIG. 5, a V-shaped SiN film 203 is formed to be thicker at the bottom of the recess 202 and thinner at the upper portion of the fine recess 202.

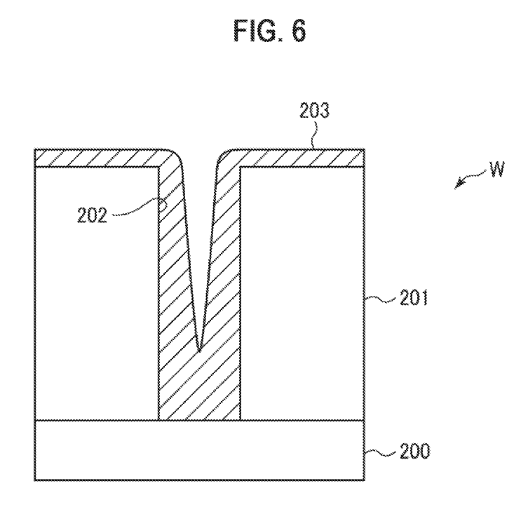

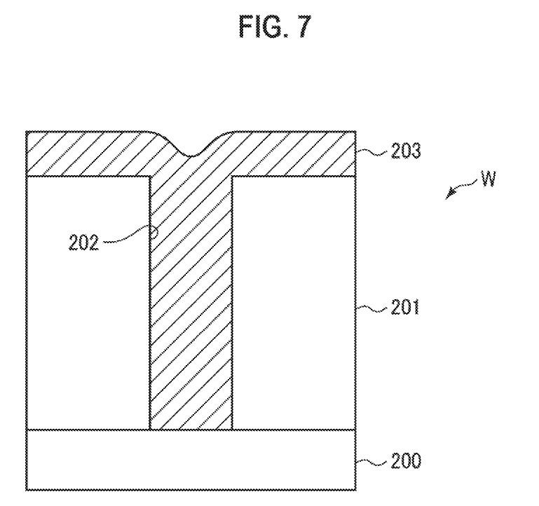

Since such a V-shaped film can be formed, when the film formation is further continued, the SiN film 203 grows bottom-up in the fine recess 202. Accordingly, the SiN film 203 can be also formed on an upper portion of a side wall of the recess 202 to such an extent that the frontage of the SiN film 203 is not narrowed, as shown in FIG. 6 and, finally, the SiN film 203 can be buried in the recess 202 in a state where no void or seam exists in the recess 202, as shown in FIG. 7.

An activation technique in the nitridation is not particularly limited but it may be preferable to adopt a technique for generating radicals immediately above a semiconductor wafer which is a substrate to be processed, and supplying H* having a short lifetime immediately above the semiconductor wafer W without being inactivated. The processing by such a method can be suitably performed by an RLSA® microwave plasma processing apparatus.

In the nitridation, a rare gas such as an Ar gas, He gas, Xe gas, Ne gas, Kr gas or the like may be used as a plasma generation gas, a dilution gas or the like.

As conditions on the above-described SiN film formation, the temperature may be in a range of 400 to 600 degrees C., specifically, 435 degrees C., and the pressure may be in a range of 66.6 to 1330 Pa, specifically, 266 Pa (2 Torr). Further, a flow rate ratio (partial pressure ratio) of the NH₃ gas to the H₂ gas (NH₃/H₂) may be in a range of 0.01 to 0.1. NH₃/H₂ corresponds approximately to NH₃*/H₂*.

As the adsorption inhibiting gas, a N₂ gas, Ar gas, He gas, Xe gas, Ne gas, Kr gas or the like may be used in addition to the H₂ gas. By converting one of these gases into radicals and supplying the radicals directly above the substrate, it is possible to obtain the same adsorption inhibiting effect as the H₂ gas. However, H₂ gas is preferable as the adsorption inhibiting gas. The Ar gas, He gas, Xe gas, Ne gas and Kr gas may be also used as a plasma gas, a dilution gas or the like. However, when being used as the adsorption inhibiting gas, they are converted into radicals immediately above the wafer and supplied to the substrate, which is different in supply form from a case of using them as the plasma gas or the dilution gas.

### Film Forming Apparatus

Next, one example of a film forming apparatus for carrying out the method for forming a nitride film according to the above embodiment will be described. In this example, a case where a SiN film is formed by using a DCS gas as a Si precursor which is a raw material gas will be described.

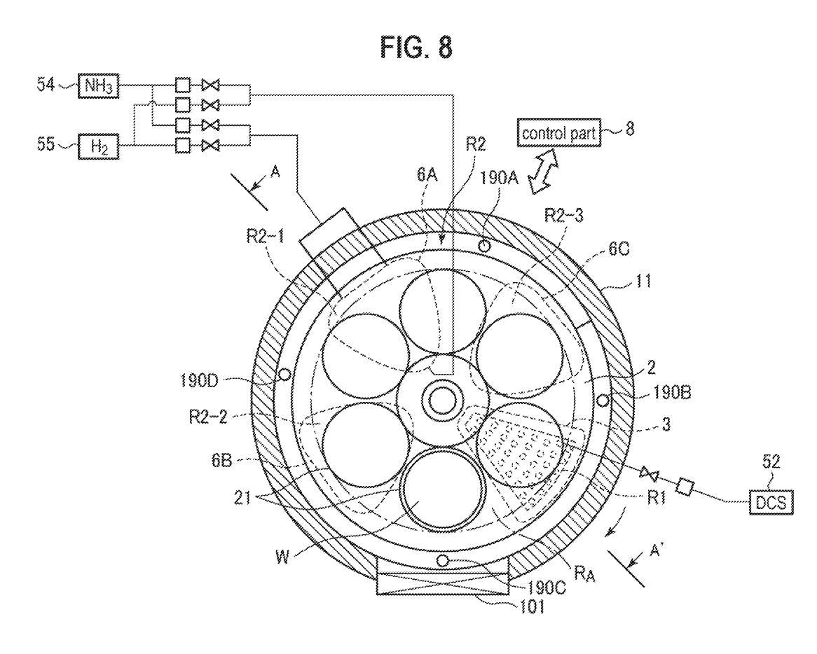

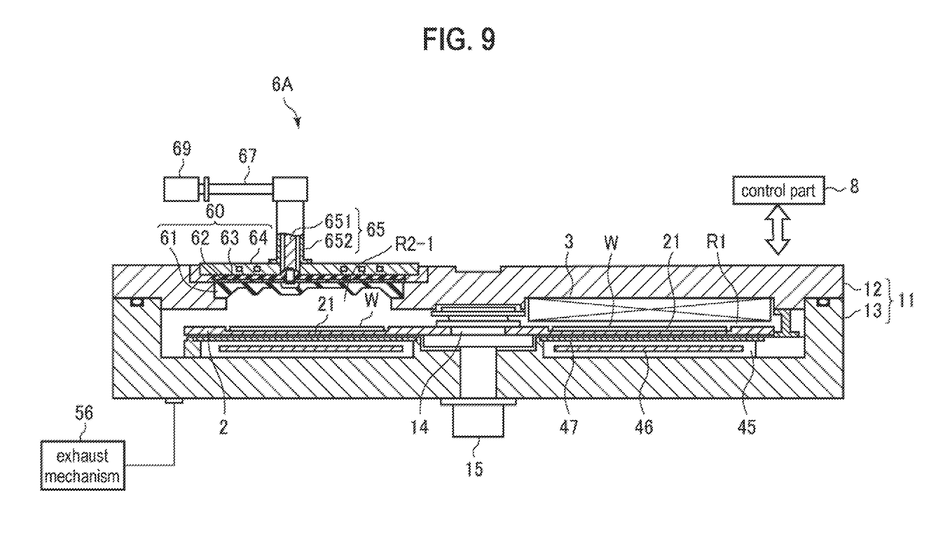

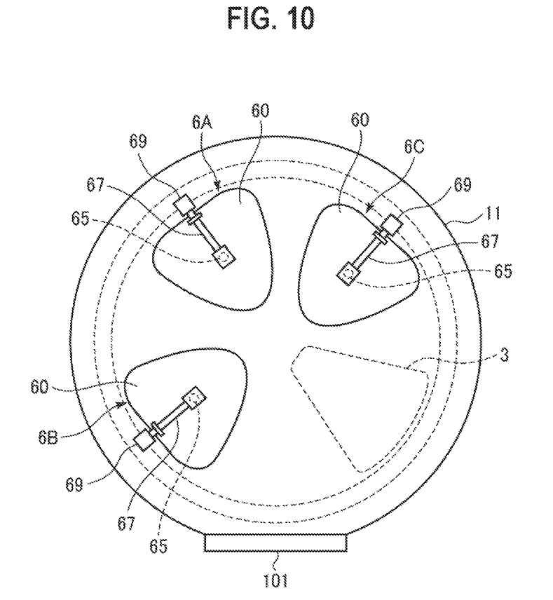

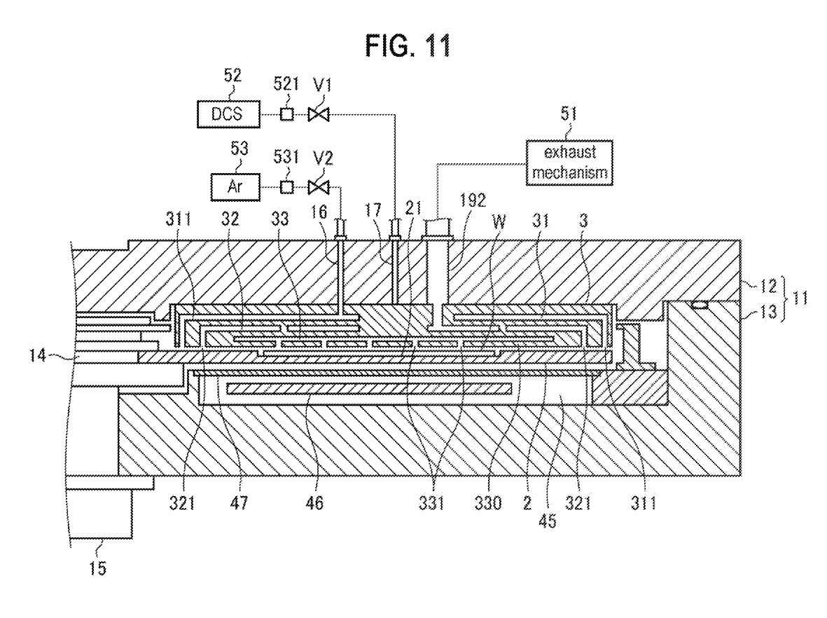

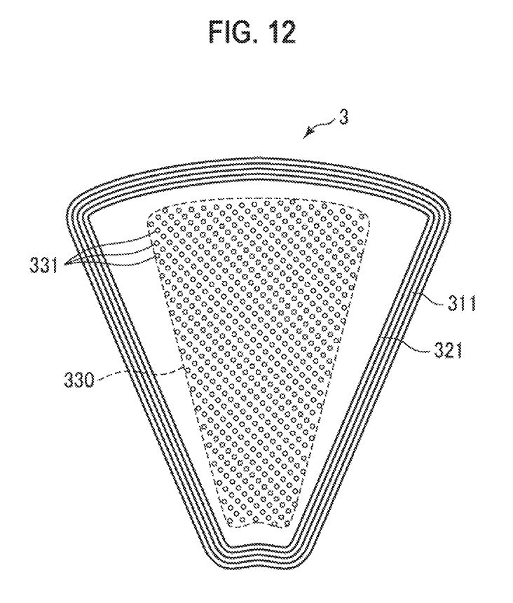

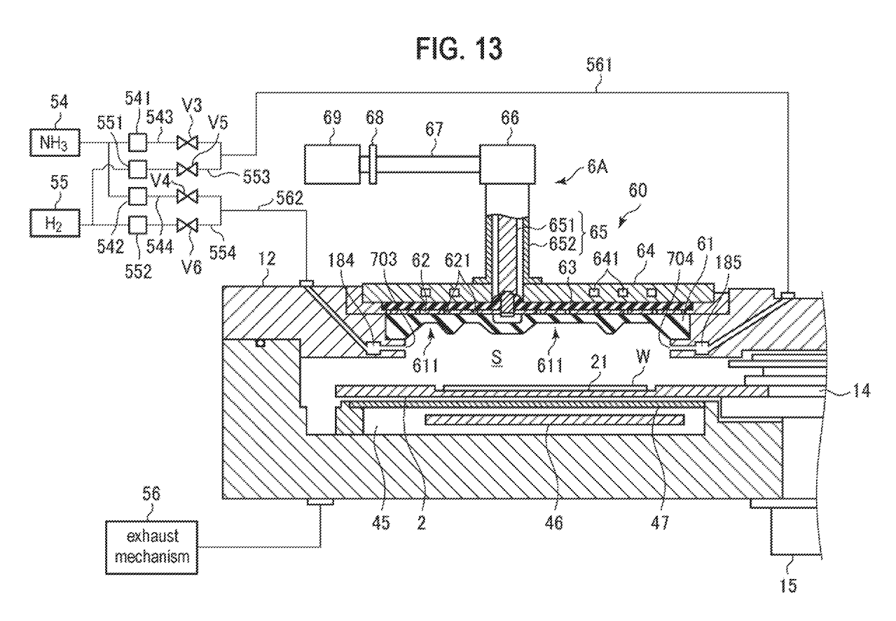

FIG. 8 is a cross-sectional view of a film forming apparatus according to this example. FIG. 9 is a longitudinal sectional view of the film forming apparatus of FIG. 8, which is taken along line A-A′ in FIG. 8. FIG. 10 is a plan view of the film forming apparatus according to this example. FIG. 11 is an enlarged longitudinal sectional view showing a first region of the film forming apparatus according to this example. FIG. 12 is a bottom view showing a precursor gas introduction unit installed in the first region. FIG. 13 is an enlarged longitudinal sectional view showing one nitriding region in a second region of the film forming apparatus according to this example.

As shown in FIGS. 8 to 11, the film forming apparatus has a vacuum container 11 which defines a processing space where a film forming process is performed. In this vacuum container 11, disposed is a rotary table 2 having a plurality of wafer mounting regions 21 formed thereon. A space above a portion of the vacuum container 11 through which the rotary table 2 passes includes a first region R1 in which a Si precursor as a raw material gas is adsorbed on the wafer W and a second region R2 in which the wafer W is subjected to nitridation. The second region R2 includes three nitriding regions, i.e., a central nitriding region R2-1 and nitriding regions R2-2 and R2-3 on both sides thereof. The side nitriding regions R2-2 and R2-3 may be used as a pre-nitridation region and a post-nitridation region, respectively.

A precursor gas introduction unit 3 for introducing the Si precursor, which is the raw material gas, into the first region R1 is disposed above the first region R1 in the vacuum container 11. A precursor gas supply source 52 is connected to the precursor gas introduction unit 3. A NH₃ gas and a H₂ gas are supplied into the nitriding region R2-1 of the second region R2 from a NH₃ gas supply source 54 and a H₂ gas supply source 55, respectively, via pipes from the outside and inside thereof. Although not shown in FIG. 9, similarly, the NH₃ gas and the H₂ gas are supplied into the nitriding regions R2-2 and R2-3. In addition, plasma generation parts 6A, 6B and 6C are disposed in the nitriding regions R2-1, R2-2 and R2-3, respectively. The gas supply system and the plasma generation parts will be described in more detail later.

As shown in FIG. 9, the vacuum container 11 is substantially a circular flat container composed of a container main body 13 forming the side wall and the bottom of the vacuum container 11, and a ceiling plate 12 for air-tightly closing an opening of the upper surface side of the container main body 13. The vacuum container 11 is made of metal such as, for example, aluminum, and the inner surface of the vacuum container 11 is subjected to plasma treatment such as anodizing treatment or ceramic spraying treatment.

For example, the surface of the rotary table 2 is subjected to the same plasma treatment as in the vacuum container 11. A rotary shaft 14 extending vertically downward is installed at the center of the rotary table 2 and a rotary drive mechanism 15 for rotating the rotary table 2 is provided at the lower end of the rotary shaft 14.

As shown in FIG. 8, six wafer mounting regions 21 are equally placed on the top surface of the rotary table 2 in the circumferential direction. Each of the wafer mounting regions 21 is configured as a circular recess having a diameter slightly larger than that of the wafer W. The number of wafer mounting regions 21 is not limited to six.

As shown in FIG. 9, an annular groove 45 is formed along the circumferential direction of the rotary table 2 on the bottom of the container main body 13 positioned below the rotary table 2. In this annular groove 45, a heater 46 is installed so as to correspond to an arrangement region of the wafer mounting regions 21. The wafer NV on the rotary table 2 is heated to a predetermined temperature by the heater 46. In addition, an opening of the top surface of the annular groove 45 is closed by a heater cover 47 which is an annular plate member.

As shown in FIGS. 8 and 10, a loading/unloading part 101 for loading and unloading the wafer W is installed in the side wall surface of the vacuum container 11. The loading/unloading part 101 can be opened and closed by a gate valve. The wafer W held by an external transfer mechanism is loaded into the vacuum container 11 via the loading/unloading part 101.

In the rotary table 2 as configured above, when the rotary table 2 is rotated by the rotary shaft 14, each wafer mounting region 21 is revolved around the rotational center of the rotary table 2. At that time, the wafer mounting region 21 passes through an annular revolution region R_{A} indicated by a one-dot chain line.

Next, the first region R1 will be described.

As shown in FIG. 9, the precursor gas introduction unit 3 in the first region R1 is installed at the bottom side of the ceiling plate 12 facing the top surface of the rotary table 2. In addition, as shown in FIG. 8, the planar shape of the precursor gas introduction unit 3 is a fan shape formed by partitioning the revolution region R_{A} of the wafer mounting region 21 in a direction intersecting the direction of revolution of the wafer mounting region 21.

As shown by enlargement in FIGS. 11 and 12, the precursor gas introduction unit 3 is structured to include a precursor gas diffusion space 33 in which the precursor gas is diffused, an exhaust space 32 in which the precursor gas is exhausted, and a separation gas diffusion space 31 in which a separation gas for separating the lower region of the precursor gas introduction unit 3 from the outer region of the precursor gas introduction unit 3 is diffused, which are stacked in this order from the lower side.

The lowermost precursor gas diffusion space 33 is connected to the precursor gas supply source 52 via a precursor gas supply path 17, an open/close valve V1 and a flow rate controller 521. For example, as a Si precursor which is a raw material gas, a DCS gas is supplied from the precursor gas supply source 52. A large number of discharge holes 331 for supplying the precursor gas from the precursor gas diffusion space 33 toward the rotary table 2 are formed in the bottom surface of the precursor gas introduction unit 3.

The discharge holes 331 are distributed in a fan-shaped region indicated by a broken line in FIG. 12. The length of two sides of the fan-shaped region extending in the radial direction of the rotary table 2 is longer than the diameter of the wafer mounting region 21. Therefore, when the wafer mounting region 21 passes below the Si precursor introduction unit 3, the Si precursor as the raw material gas is supplied from the discharge holes 331 onto the entire surface of the wafer W mounted in the wafer mounting region 21.

The fan-shaped region provided with the large number of discharge holes 331 constitutes a discharge part 330 of a film forming precursor gas. A precursor gas supply part is constituted by the discharge part 330, the precursor gas diffusion space 33, the precursor gas supply path 17, the open/close valve V1, the flow rate controller 521 and the precursor gas supply source 52.

As shown in FIGS. 11 and 12, the exhaust space 32 formed above the precursor gas diffusion space 33 communicates with an exhaust port 321 extending along a closed path surrounding the discharge part 330. In addition, the exhaust space 32 is connected to an exhaust mechanism 51 via an exhaust path 192 and has an independent flow path which leads the precursor gas, which is supplied below the precursor gas introduction unit 3 from the precursor gas diffusion space 33, to the exhaust mechanism 51. An exhaust part is constituted by the exhaust port 321, the exhaust space 32, the exhaust path 192 and the exhaust mechanism 51.

Further, the separation gas diffusion space 31 formed above the exhaust space 32 communicates with a separation gas supply port 311 extending along a closed path surrounding the exhaust port 321. Further, the separation gas diffusion space 31 is connected to a separation gas supply source 53 via a separation gas supply path 16, an open/close valve V2 and a flow rate controller 531. A separation gas which separates the inside and outside atmospheres of the separation gas supply port 311 and which also functions as a purge gas for removing the precursor gas excessively adsorbed onto the wafer W is supplied from the separation gas supply source 53. As the separation gas, an inert gas such as an Ar gas is used. A separation gas supply part is constituted by the separation gas supply port 311, the separation gas diffusion space 31, the separation gas supply path 16, the open/close valve V2, the flow rate controller 531 and the separation gas supply source 53.

In the precursor gas introduction unit 3, the precursor gas supplied from each discharge hole 331 of the discharge part 330 spreads around while flowing over the rotary table 2, eventually reaches the exhaust port 321 and is exhausted from the top surface of the rotary table 2. Therefore, in the vacuum container 11, a region where the precursor gas is present is limited to the inside of the exhaust port 321 disposed along a first closed path. Since the precursor gas introduction unit 3 has a shape in which a part of the revolution region R_{A} of the wafer mounting region 21 is partitioned in a direction intersecting with the revolution direction of the wafer mounting region 21, when the rotary table 2 is rotated, the wafer W mounted in each wafer mounting region 21 passes through the first region R1 and the precursor gas is adsorbed onto the entire surface of the wafer W.

On the other hand, around the exhaust port 321, the separation gas supply port 311 is disposed along a second closed path and a separation gas is supplied from the separation gas supply port 311 toward the top surface of the rotary table 2. Therefore, the inside and outside of the first region R1 are doubly separated by the exhaust gas from the exhaust port 321 and the separation gas supplied from the separation gas supply port 311 thereby effectively preventing leakage of the precursor gas to the outside of the first region R1 and introduction of a reaction gas component from the outside of the first region R1.

The range of the first region R1 may be a range in which a sufficient contact time can be secured for adsorbing the precursor gas on the entire surface of the wafer W and in which the first region R1 does not interfere with the second region R2 in which the nitridation is performed, the second region R2 being formed outside the first region R1.

Next, the second region R2 will be described. As described above, the second region R2 has three nitriding regions R2-1, R2-2 and R2-3 provided with the respective plasma generation parts 6A, 6B and 6C. The NH₃ gas and the H₂ gas are supplied from the NH₃ gas supply source 54 and the H₂ gas supply source 55 from the outside and inside thereof via pipes.

As shown in FIG. 13, the plasma generation part 6A of the nitriding region R2-1 includes an antenna part 60 which radiates a microwave toward the inside of the vacuum container 11, a coaxial waveguide 65 which supplies a microwave toward the antenna part 60, and a microwave generator 69, and is configured with an RLSA® microwave plasma processing apparatus. The antenna part 60 is installed so as to close a triangular opening formed in the ceiling plate 12 facing the top surface of the rotary table 2.

The microwave generator 69 generates a microwave having a frequency of, for example, 2.45 GHz. A waveguide 67 is connected to the microwave generator 69 and a tuner 68 for impedance matching is installed in the waveguide 67. The waveguide 67 is connected to a mode converter 66 and the coaxial waveguide 65 extending downward is connected to the mode converter 66. In addition, the antenna part 60 is connected to the lower end of the coaxial waveguide 65. Then, the microwave generated by the microwave generator 69 propagates to the antenna part 60 via the waveguide 67, the mode converter 66 and the coaxial waveguide 65. The mode converter 66 converts a mode of the microwave into a mode capable of guiding the microwave to the coaxial waveguide 65. The coaxial waveguide 65 has an inner conductor 651 and an outer conductor 652 coaxial with the inner conductor 651.

The antenna part 60 is configured with an RLSA® antenna including a dielectric window 61, a planar slot antenna 62, a retardation member 63 and a cooling jacket 64.

The planar slot antenna 62 is configured h an approximately triangular metal plate and has a number of slots 621 formed therein. The slots 621 are appropriately set so as to radiate the microwave efficiently. For example, the slots 621 are arranged at predetermined intervals in the radial direction from the center of the above-mentioned triangular shape to the periphery thereof and in the circumferential direction and are formed such that adjacent slots 621 and 621 intersect with each other or are orthogonal to each other.

The dielectric window 61, which is made of ceramics such as alumina, has a function to pass the microwave therethrough, which is transmitted from the coaxial waveguide 65 and radiated from the slots 621 of the planar slot antenna 62, and to generate surface wave plasma uniformly in a space above the rotary table 2. The dielectric window 61 is made, e.g., ceramics such as alumina or the like, and has a triangular planar shape capable of blocking the opening of the ceiling plate 12. An annular recess 611 having a tapered surface for stably generating plasma by concentrating microwave energy is formed in the bottom surface of the dielectric window 61. The bottom surface of the dielectric window 61 may be planar.

The retardation member 63 is installed on the planar slot antenna 62 and is made of a dielectric material having a dielectric constant larger than that of vacuum, for example, ceramics such as alumina. The retardation member 63 is provided to shorten the wavelength of the microwave and has substantially a triangular planar shape corresponding to the dielectric window 61 and the planar slot antenna 62. The cooling jacket 64 is installed on the retardation member 63. A coolant flow path 641 is formed inside the cooling jacket 64 and the antenna part 60 can be cooled by flowing a coolant through the coolant flow path 641.

Then, the microwave generated by the microwave generator 69 passes through the slot 621 of the planar slot antenna 62 via the waveguide 67, the mode converter 66, the coaxial waveguide 65 and the retardation member 63 and is supplied to a space S immediately above the wafer W under the dielectric window 61 through the dielectric window 61.

A plurality of (e.g., 2) peripheral side gas discharge holes 703 for discharging a gas for nitridation into the space S where plasma is generated are formed in the periphery of a portion supporting the dielectric window 61 of the ceiling plate 12. The peripheral side gas discharge holes 703 are arranged with a space therebetween. The peripheral side gas discharge holes 703 communicate with a peripheral side gas supply path 184 opened to the top surface of the ceiling plate 12. A pipe 562 is connected to the peripheral side gas supply path 184. The NH₃ gas supply source 54 and the H₂ gas supply source 55 are connected to the pipe 562 via a pipe 544 and a pipe 554. An open/close valve V4 and a flow rate controller 542 are installed in the pipe 544 and an open/close valve V6 and a flow rate controller 552 are installed in the pipe 554.

On the other hand, a central side gas discharge hole 704 for discharging a gas for nitridation into the space S where plasma is generated is formed in the center of the portion supporting the dielectric window 61 of the ceiling plate 12. The central side gas discharge hole 704 communicates with a central side gas supply path 185 opened to the top surface of the ceiling plate 12. A pipe 561 is connected to the central side gas supply path 185. The NH₃ gas supply source 54 and the H₂ gas supply source 55 are connected to the pipe 561 via a pipe 543 and a pipe 553. An open/close valve V3 and a flow rate controller 541 are installed in the pipe 543 and an open/close valve V5 and a flow rate controller 551 are installed in the pipe 553. These components constitute a nitriding gas supply part.

Thus, the NH₃ gas and the H₂ gas are supplied into the space S immediately above the wafer (W) passing region into which the microwave is supplied and NH₃* and H₂* are generated in a region immediately above the wafer (W) passing region.

Note that a separate gas supply line may be provided to supply a rare gas such as an Ar gas, as a plasma generation gas, to a position immediately under the dielectric window 61.

The plasma generation parts 6B and 6C of the other nitriding regions R2-2 and R2-3 are also configured exactly in the same manner as the plasma generation part 6A of the above-described nitriding region R2-1. The supply of the NH₃ gas and the H₂ gas from the NH₃ gas supply source 54 and the H₂ gas supply source 55 in the nitriding regions R2-2 and R2-3 is also performed in the same manner as that in the nitriding region R2-1.

The processing space of the second region R2 in which the nitridation is performed is exhausted by the exhaust mechanism 56 via four exhaust ports 190A, 190B, 190C and 190D uniformly installed in the outer edge of the bottom of the container main body 13 of the vacuum container 11, as shown in FIG. 8.

As shown in FIG. 8, the film forming apparatus includes a control part 8. The control part 8 is constituted by a computer having a CPU and a storage part and controls various components of the film forming apparatus, for example, the rotary drive mechanism 15 for rotating the rotary table 2, the precursor gas supply part, the separation gas supply part, the nitriding as supply part, the plasma generation parts 6A to 6C, and the like. A control program for giving instructions to the various components for executing a predetermined film forming process with the film forming apparatus, that is, process recipes, various databases and the like are stored in the storage part. The process recipes and the like are stored in a storage medium. The storage medium may be a hard disk built in the computer or may be a portable medium such as a CD ROM, a DVD, a semiconductor memory or the like. Further, the process recipes and the like may be transmitted from another device via an appropriate line.

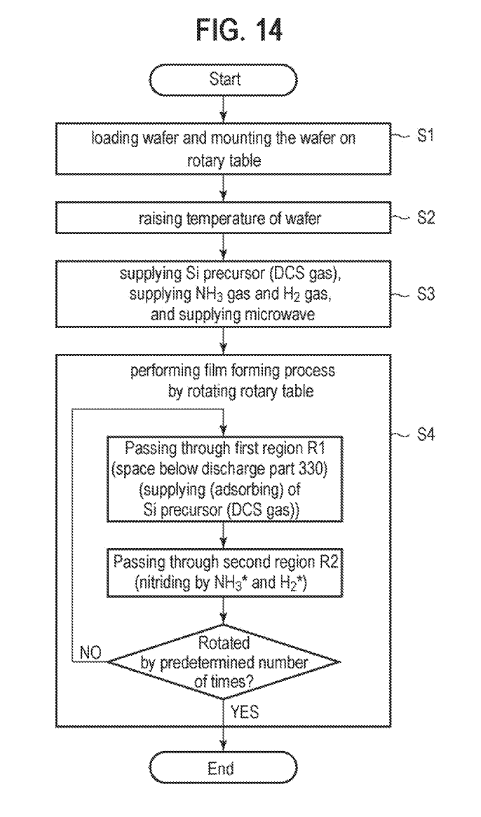

Next, the processing operation of the film forming apparatus configured as above will be described with reference to a flow chart of FIG. 14.

First, the gate valve of the loading/unloading part 101 is opened and a wafer W is loaded into the vacuum container 11 by an external transfer mechanism and is mounted on the wafer mounting region 21 of the rotary table 2 (Step S1). The transfer of the wafer W is performed by intermittently rotating the rotary table 2 and wafers W are mounted on all of the wafer mounting regions 21. When the mounting of the wafers W is completed, the transfer mechanism is retracted and the gate valve of the loading/unloading part 101 is closed. At this time, the interior of the vacuum container 11 is evacuated to a predetermined pressure in advance by the exhaust mechanisms 51 and 56. In addition, as the separation gas, for example, an Ar gas is supplied from the separation gas supply port 311.

Thereafter, the temperature of the wafer W is raised to a predetermined set temperature by the rotary table 2 set at a predetermined temperature in a range of 400 to 600 degrees C. by the heater 46 based on a detection value of a temperature sensor (not shown) (Step S2).

At the point of time when the wafer W reaches the predetermined set temperature, supply of a Si precursor into the first region R1 in the vacuum container 11, supply of a NH₃ gas and a H₂ gas for nitridation into the second region R2, and supply of a microwave from the plasma generation parts 6A to 6C are started (Step S3).

Thereafter, the rotary table 2 is rotated in a clockwise direction at a preset rotation speed and a film forming process is performed (Step S4).

At this time, as the Si precursor, which is a raw material gas, a DCS gas is supplied into the first region R1 from the discharge part 330 of the precursor gas introduction unit 3 in a range of flow rate of, for example, 600 to 1200 sccm and the NH₃ gas and the H₂ gas for nitridation are supplied into second region R2 from the peripheral side gas discharge holes 703 and the central side gas discharge hole 704 of the nitriding regions R2-1, R2-2 and R2-3 in a range of flow rate of, for example, 10 to 1000 sccm and 2000 to 8000 sccm respectively. By turning on the microwave generator 69 of the plasma generation parts 6A to 6C, a microwave is supplied into the space S immediately above the wafer (W) passing region. At that time, the internal pressure of the vacuum container 11 is set to fall within a range of, for example, 66.6 to 1330 Pa. Further, the microwave power is set to, for example, 1000 to 2500 W.

Thus, in the vacuum container 11, in the first region R1, the precursor gas supplied from the discharge part 330 of the precursor gas introduction unit 3 is flown into a limited region up to the exhaust port 321 surrounding the discharge part 330. On the other hand, in the second region R2, the NH₃ gas and the H₂ gas discharged from the peripheral side gas discharge holes 703 and the central side discharge hole of the nitriding regions R2-1, R2-2 and R2-3 are converted into NH₃* and H₂*, respectively, by being converted into plasma by the microwave supplied from the antenna part 60 of the plasma generation parts 6A, 6B and 6C, which are exhausted from the exhaust ports 190A, 19013, 190C and 190D. In addition, the atmosphere in the first region R1 and the atmosphere in the second region R2 are separated from each other by the separation gas.

In this manner, when the DCS gas which is the raw material gas (Si precursor) is supplied into the first region R1 and the NH₃* and H₂* are supplied into the second region R2, the wafer W mounted in each wafer mounting region 21 of the rotary table 2 alternately repeatedly passes through the first region R1 and the second region R2 as the rotary table 2 is rotated. Thus, the DCS gas as the precursor gas, the Ar gas as the separation gas (purge gas), the NH₃* and H₂* and the Ar gas as the separation gas (purge gas) are sequentially supplied onto the wafer W, a SiN film is formed by the film farming technique based on the ALD method, and the SiN film is buried in the fine trench formed in the wafer W. Then, at the point of time when the number of rotations of the rotary table 2 reaches a predetermined number of times, the burying of SiN is ended.

At this time, in the second region R2, in each of the nitriding regions R2-1, R2-2 and R2-3, plasma is generated by the microwave in each of the plasma generation parts 6A, 6B and 6C, the NH₃ gas as a nitriding gas and the H₂ gas as an adsorption inhibiting gas are excited into NH₃* and H₂*, respectively, by the plasma, which are supplied onto the wafer W. At this time, since the NH₃* and H₂* are generated immediately above the wafer (W) passing region in each of the nitriding regions R2-1, R2-2 and R2-3, the H₂* having a short lifetime is also supplied onto the wafer W while maintaining the state of H₂*.

On the other hand, as described above, since the lifetime of H₂* is short, the adsorption inhibiting effect of H₂* is larger at the upper portion of the trench and smaller at the bottom of the trench. For this reason, the adsorption site of NH₃* becomes relatively small at the upper portion of the recess and becomes relatively large at the bottom portion of the recess.

Therefore, in the process of depositing the SiN film, the nitriding reaction of DCS as the film forming raw material is more likely to proceed at the bottom of the trench than at the upper portion of the trench, the film formation proceeds in a state where the film maintains a V shape, thereby making it possible to bury the SiN film in the trench in the absence of voids and seams.

Further, since the film forming apparatus can perform the film forming process on a plurality of waters at one time, a throughput is high.

### Other Applications

Although the embodiments of the present disclosure have been described above, the present disclosure is not limited to the above embodiments, but various modifications can be made without departing from the spirit of the invention.

For example, the case where the silicon precursor and NH₃* and H₂* are used to form the silicon nitride film has been described by way of example in the above embodiment, but the present disclosure is not limited to this case but may be applied to any case where a nitride film is formed by NH₃* and H₂*. For example, the present disclosure may be applied to various nitride films, such as a case where a TiN film is formed using a Ti precursor, a case where a BN film is formed using a B precursor, a case where a WN film is formed using a W precursor, etc.

Also, the film forming apparatus is not limited to those exemplified above but may be any apparatus as long as it can supply H₂* radicals onto a substrate to be processed without deactivating the radicals. In addition, the case where the rotary table on which a plurality of wafers are mounted is rotated to pass the wafers through the first region where the precursor gas is adsorbed and the second region R2 where the nitridation is performed to form a nitride film has been described in the above embodiment. However, it is also possible to use a single wafer type film forming apparatus in which supply, purge, nitridation and purge of a precursor gas are repeated.

According to the present disclosure in some embodiments, in forming a nitride film in a fine recess by repeating a first step of adsorbing a film forming raw material gas and a second step of nitriding the adsorbed film forming raw material gas, the second step is performed by converting a NH₃ gas as a nitriding gas and an adsorption inhibiting gas which inhibits adsorption of the NH₃ gas into radicals and supplying them onto a substrate to be processed. At this time, by using a gas including radicals having short lifetime as the adsorption inhibiting gas, it is possible to provide less adsorption inhibition gas radicals at the bottom of the recess than at the upper portion of the recess and to increase the adsorption amount of NH₃ radicals at the bottom of the recess. Therefore, it is possible to proceed with film formation in a V-shaped recess which is thicker at the bottom of the recess and thinner at the upper portion of the recess and it is possible to bury a nitride film in a state in which voids or seams are not present in the recess.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a nitride film in a fine recess formed in a surface of a substrate to be processed, by repeating a process comprising:
adsorbing a film forming raw material gas onto the substrate; and
nitriding the adsorbed film forming raw material gas,
wherein the nitriding the adsorbed film forming raw material gas includes converting a NH₃ gas as a nitriding gas, and an adsorption inhibiting gas for inhibiting adsorption of the NH3 gas into radicals and supplying the radicals onto the substrate.

2. The method of claim 1, wherein a H2 gas is used as the adsorption inhibiting gas.

3. The method of claim 2, wherein a flow rate ratio NH₃/H₂ of the NH₃ gas to the H₂ gas falls within a range of 0.01 to 0.1.

4. The method of claim 1, wherein the converting into radicals is performed by generating microwave plasma immediately above the substrate.

5. The method of claim 1, wherein the adsorbing a film forming raw material gas and the nitriding the adsorbed film forming raw material gas are performed by providing a first region in which the adsorbing a film forming raw material gas is performed and a second region in which the nitriding the adsorbed film forming raw material gas is performed, in a vacuum container and revolving a plurality of substrates to be processed, which are mounted on a rotary table in the vacuum container, so that the substrates to be processed sequentially pass through the first region and the second region.

6. The method of claim 1, wherein a Si precursor is used as the film forming raw material gas to form a silicon nitride film.
